(19) United States
(12) Patent Application Publication
(10) Pub. No.: US 2026/0353942 A1
(43) Pub. Date: Nov. 5, 2026

(54) DISPLAY DEVICE

(71) Applicant: LG Display Co., Ltd., Seoul (KR)

(72) Inventors: Hyekyung CHOI, Seoul (KR); UngGi LEE, Paju-si (KR); SeoHui JUNG, Goyang-si (KR); Yongbong LEE, Jeju-si (KR); Yujin LEE, Goyang-si (KR)

(21) Appl. No.: 19/558,183

(22) Filed: Mar. 5, 2026

(30) Foreign Application Priority Data
Apr. 30, 2025 (KR) 10-2025-0057524

(51) Int. Cl. H10K 59/124; H10K 59/122; H10K 59/131

(52) U.S. Cl. CPC H10K 59/124; H10K 59/122; H10K 59/131

(57) ABSTRACT

A display device includes a substrate including a display area and a non-display area, an insulating layer and a planarization layer disposed above the substrate and extending from the display area to non-display area, at least one trench disposed in the non-display area and configured by removing at least one of the insulating layer and the planarization layer, a bank disposed on the planarization layer and extending to the non-display area, an organic layer disposed on the bank, a cathode disposed on the organic layer and extending to the trench, a gate pad part disposed on a first side of the non-display area, a data pad part disposed on a second side of the non-display area, and a plurality of open holes configured by removing the planarization layer from the data pad part, and suppressing moisture and oxygen penetration while reducing bezel width to improve moisture and oxygen barrier performance.

### CROSSREFERENCE TO RELATED APPLICATION

This application claims priority from and the benefit of Korean Patent Application No. 10-2025-0057524, filed on Apr. 30, 2025, which is hereby incorporated by reference for all purposes as if fully set forth herein.

### BACKGROUND

### Field

Embodiments of the invention relate generally to a display device, and more particularly, to a display device capable of preventing moisture permeation and oxygen permeation.

### Discussion of the Background

Currently, as it enters a full-fledged information era, the field of display devices that visually display electrical information signals is rapidly developing. Ongoing research is focused on improving performance characteristics of various display devices, including reduced thickness and weight, as well as low power consumption.

Representative display devices include a liquid crystal display (LCD), an electro-wetting display (EWD), and an organic light emitting display (OLED).

Among them, an electroluminescent display device including an organic light emitting display device is a self-emitting display device and does not require a separate light source, unlike a liquid crystal display device, and thus may be manufactured to have light weight and small thickness. In addition, the electroluminescent display device is advantageous not only in terms of power consumption due to low voltage driving, but also in terms of color reproduction, response speed, viewing angle, and contrast ratio, so that it is expected to be used in various fields.

In the electroluminescent display device, a bezel interval having a predetermined level or higher is required to block permeation of moisture and oxygen from the outside and secure long-term reliability. However, in the deposition process of the cathode and the organic layer, a shadow area occurs due to a gap formed between the mask and the substrate, which acts as a technical constraint on reducing the bezel to a certain level or less. In addition, as the bezel becomes thinner, the thickness of the cathode and the insulating layer also decreases, and such a thin-film structure becomes more vulnerable to the penetration of oxygen and moisture from the external environment. As a result, deterioration of the organic light emitting device is accelerated, and a dark spot defect may occur.

The above information disclosed in this Background section is only for understanding of the background of the inventive concepts, and, therefore, it may contain information that does not constitute prior art.

### SUMMARY

Embodiments of the invention provide a display device which blocks moisture and oxygen while reducing a bezel width.

Embodiments of the invention provide a display device which improves a reliability and lifetime and secures a manufacturing efficiency and a degree of design freedom.

Additional features of the inventive concepts will be set forth in the description which follows, and in part will be apparent from the description, or may be learned by practice of the inventive concepts.

A display device according to an embodiment of the invention includes a substrate including a display area and a non-display area, an insulating layer and a planarization layer disposed on the substrate and extending from the display area to the non-display area, at least one trench disposed in the non-display area and configured by removing at least one of the insulating layer and the planarization layer, a bank disposed on the planarization layer and extending to the non-display area, an organic layer disposed on the bank, a cathode disposed on the organic layer and extending to the trench, a gate pad part disposed on a first side of the non-display area, a data pad part disposed on a second side of the non-display area, and a plurality of open holes configured by removing the planarization layer on the data pad part.

The trench may be disposed to surround the display area except for the second side.

The display device may further include a gate-in-panel (GIP) circuit part disposed in the gate pad part, and the GIP circuit part may be disposed on an inner side of the trench.

The display device may further include a first power line disposed inside the trench and covering an inside of the trench.

The cathode may extend into the trench to cover a part of a top surface of the first power line, and the cathode may be in contact with the top surface of the first power line.

The display device may further include a protective layer disposed on the cathode, in the non-display area on the second side, the protective layer may cover a part of a top surface of the cathode, and in the non-display area other than the second side, the protective layer may be disposed to surround the cathode.

The trench may include a first trench disposed over the non-display area excluding the second side, and a second trench positioned on an inner side of the first trench and disposed over the non-display area of four sides.

The first trench may be configured by removing a partial area of the insulating layer and the planarization layer in the non-display area, and the second trench may be configured by removing a partial area of the planarization layer in the non-display area.

A plurality of second trenches may be disposed, and a plurality of dams configured as the planarization layer may be disposed between the plurality of second trenches.

The display device may further include a first-1 power line disposed in the first trench to cover an inside of the first trench and a first-2 power line disposed in the second trench to cover aninside of the second trench.

The display device may further include a first line disposed over the substrate of the data pad part and a buffer layer disposed over the first line and patterned into an island shape in an area where the open hole is located.

A plurality of contact holes may be formed in the buffer layer to expose a top surface of the first line.

The display device may further include a low potential driving voltage line disposed on the buffer layer, and the low potential driving voltage line may be electrically connected to the first line through the contact hole.

In a plan view, the open hole may have an inverted triangle or an inverted trapezoidal shape that narrows in a downward direction.

The display device may further include a second line disposed in the open hole and a connection electrode disposed in a connection portion at both upper ends of the open hole based on a plane, and in the non-display area of the second side, the planarization layer and the bank may be disposed in a remaining area excluding the open hole and the connection portion.

The organic layer may extend into the open hole to cover a part of the second line in the open hole, the cathode may extend into the open hole to cover an organic layer in the open hole and a part of a top surface of the second line, and the cathode may be in contact with the top surface of the second line.

An encapsulation substrate is disposed over the cathode above with an adhesive layer interposed therebetween, and the adhesive layer may further include adsorption particles.

The adsorbent particles may include reduced metal oxide (MOn-x).

The display device may further include a protective layer disposed on the cathode, the cathode may extend to the non-display area to cover the entire open hole, and the protective layer may extend to the non-display area to surround the cathode.

A display device according to another embodiment of the invention includes a substrate including a display area and a non-display area having four sides disposed to surround the display area, a first trench disposed over three sides excluding one side of the non-display area and configured by removing a portion of an insulating layer and a planarization layer, a second trench disposed over the non-display area of the four sides and on an inner side of the first trench, and configured by removing the planarization layer, and a plurality of open holes formed on one side of the non-display area and outside the second trench and configured by removing the planarization layer.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view of a display device according to a first embodiment of the invention.

FIG. 2 is a cross-sectional view of a sub pixel of the display device of FIG. 1.

FIG. 3 is a cross-sectional view taken along line Ia-Ia' of FIG. 1.

FIG. 4 is a cross-sectional view taken along line Ib-Ib' of FIG. 1.

FIG. 5 is a cross-sectional view taken along line Ic-Ic' of the display device of FIG. 1.

FIG. 6 is an enlarged view of part A of FIG. 1.

FIG. 7 is a cross-sectional view taken along line A-A' in FIG. 6.

FIG. 8 is a cross-sectional view taken along line B-B' in FIG. 6.

FIG. 9 is a plan view of a display device according to a second embodiment of the invention.

FIG. 10 is a cross-sectional view taken along line IIa-IIa' of FIG. 9.

FIG. 11 is a cross-sectional view taken along line IIb-IIb' of FIG. 9.

FIG. 12 is an enlarged view of part B of FIG. 9.

FIG. 13 is a cross-sectional view taken along line C-C' of FIG. 12.

FIG. 14 is a cross-sectional view of a display device according to a third embodiment of the invention.

FIG. 15 is a cross-sectional view of a display device according to a fourth embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

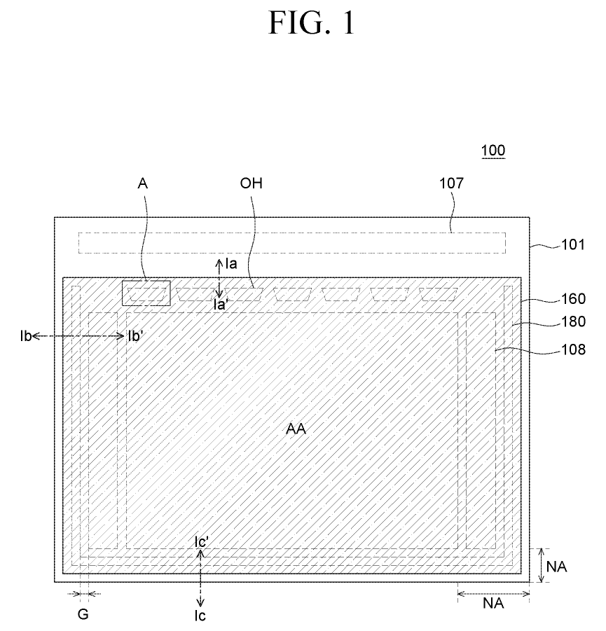

FIG. 1 is a plan view of a display device according to an embodiment of the invention.

Referring to FIG. 1, a display device 100 according to an embodiment of the invention may include a substrate 111, an encapsulation substrate 160, and pad parts 107 and 108.

The display device 100 is a device for displaying an image to a user.

In the display device 100, a display element for displaying images, a driving element for driving the display element, and lines for transmitting various signals to the display element and the driving element may be disposed. The display element may be differently defined depending on the type of the display device 100, and for example, when the display device 100 is an organic light emitting display device, the display element may be an organic light emitting element including an anode, an organic emission layer, and a cathode. For example, when the display device 100 is a liquid crystal display device, the display element may be a liquid crystal display element.

Hereinafter, even though it is assumed that the display device 100 is an organic light emitting display device, the display device 100 is not limited to being the organic light emitting display device.

The display device 100 may include a display area AA and a non-display area NA.

The display area AA is an area in which images are displayed in the display device 100.

In the display area AA, a plurality of sub pixels constituting a plurality of pixels and a circuit for driving the plurality of sub pixels may be disposed. The plurality of sub pixels are minimum units constituting the display area AA, and a display element may be disposed in each of the plurality of sub pixels, and the plurality of sub pixels may constitute a pixel. For example, an organic light emitting element including an anode, an organic emission layer, and a cathode may be disposed in each of the plurality of sub pixels, but is not limited thereto. Further, a circuit for driving the plurality of sub pixels may include a driving element, a line, and the like. For example, the circuit may include a thin film transistor, a storage capacitor, a gate line, a data line, and the like, but is not limited thereto.

The non-display area NA is an area where no image is displayed.

FIG. 1 illustrates that the non-display area NA encloses the display area AA having a rectangular shape. However, the shapes and arrangements of the display area AA and the non-display area NA are not limited to the example illustrated in FIG. 1.

In other words, the display area AA and the non-display area NA may have shapes suitable for the design of an electronic device equipped with the display device 100. For example, the display area AA may have various shapes, such as a pentagon, a hexagon, a circle, an oval, or other suitable shapes.

In the non-display area NA, various lines and circuits for driving the organic light emitting element of the display area AA may be disposed. For example, in the non-display area NA, link lines for transmitting signals to the plurality of sub pixels and circuits of the display area AA, driving ICs such as gate driver ICs and data driver ICs or pad parts 107 and 108 may be disposed, but are not limited thereto.

The pad parts 107 and 108 may be disposed to receive signals from the outside.

The pad parts 107 and 108 may be disposed in the non-display area NA of the display device 100 to be electrically connected to various lines and printed circuit boards disposed in the display area AA.

For example, the pad parts 107 and 108 may function to transmit a signal to each of the gate line and the data line, and include a gate pad part 108 to transmit a gate signal to the gate line and a data pad part 107 to transmit a data signal to the data line, but are not limited thereto.

The gate pad part 108 may be disposed on at least one side of the display device 100, for example, in the non-display area NA on the first side, but is not limited thereto. In this case, the first side may mean one of left and right sides of the display device 100 adjacent to the upper and lower sides.

The data pad part 107 may be disposed in the non-display area NA on the other side of the display device 100, for example, the second side, but is not limited thereto. For example, the second side may refer to an upper side of the display device 100, but is not limited thereto.

For example, the data pad part 107 may be electrically connected to a data driver to supply a data voltage to a plurality of data lines. The data driver may receive image data from the timing controller and supply a data voltage to the plurality of data lines to drive the plurality of data lines. The data driver may be implemented by including one or more source driver integrated circuits.

Meanwhile, the gate driver may drive a plurality of gate lines by outputting a scan signal to the plurality of gate lines. For example, the gate driver may sequentially drive the plurality of gate lines by sequentially supplying scan signals to the plurality of gate lines. The gate driver may sequentially supply an on voltage or an off voltage scan signal to the plurality of gate lines under the control of the timing controller.

The gate driver may include a plurality of gate driving circuits. Here, the plurality of gate driving circuits may correspond to the plurality of gate lines, respectively.

Each gate driving circuit may be implemented in a gate-in-panel (GIP) type and embedded in the display device 100. For example, each gate driving circuit may be directly disposed on the gate pad part 108, and in this case, the gate pad part 108 may be referred to as a GIP circuit part.

Meanwhile, in the display device 100 according to the first embodiment of the invention, the trench 180 may be provided in the non-display area NA to secure reliability such as prevention of moisture permeation.

The trench 180 may be disposed to surround the display area AA except for the upper side, but is not limited thereto.

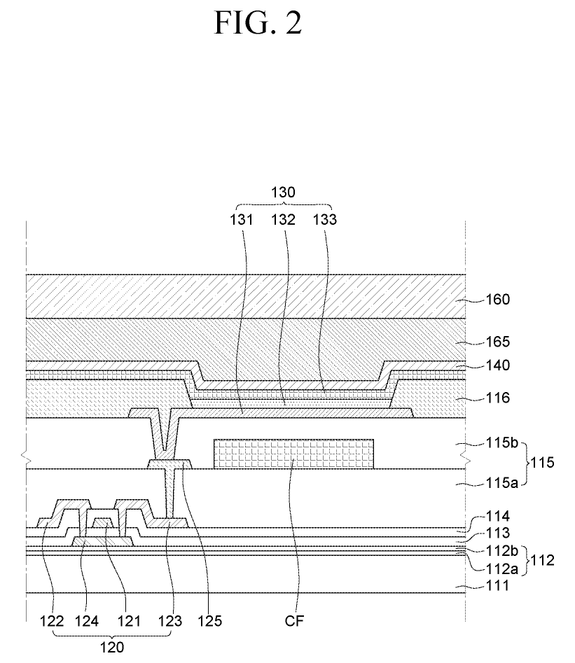

Further, in the display device 100 according to the first embodiment of the invention, the GIP circuit part 108 is disposed on an inner side of the trench 180 (e.g., towards an inner portion of the display device 100) while being spaced apart from the trench 180 at a predetermined interval G so that the moisture permeation effect on the GIP circuit part 108 may be minimized, which will be described in detail with reference to FIGS. 2 to 5.

FIG. 2 is a cross-sectional view of a sub pixel of the display device of FIG. 1.

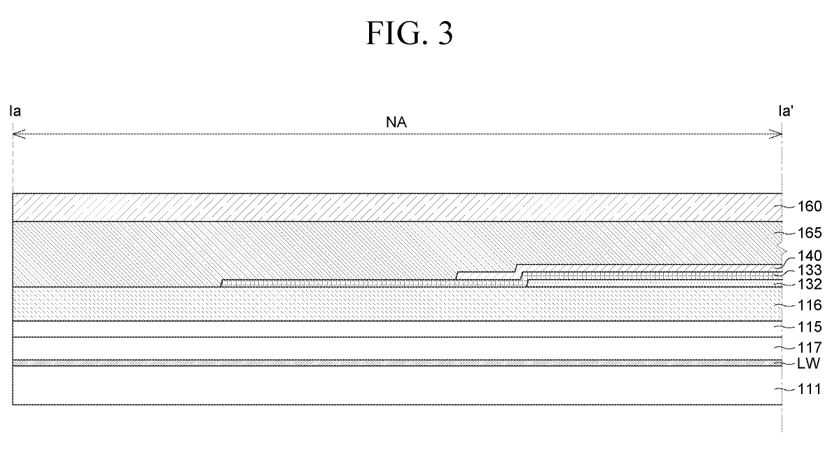

FIG. 3 is a cross-sectional view taken along line Ia-Ia' of FIG. 1.

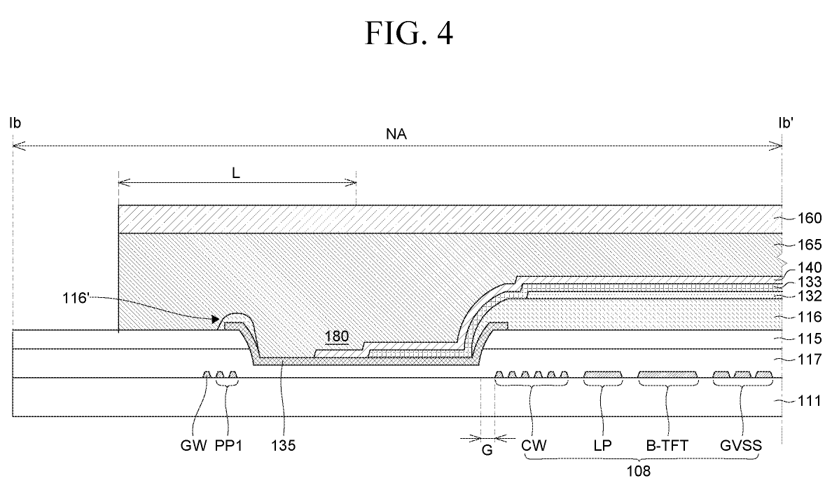

FIG. 4 is a cross-sectional view taken along line Ib-Ib' of FIG. 1.

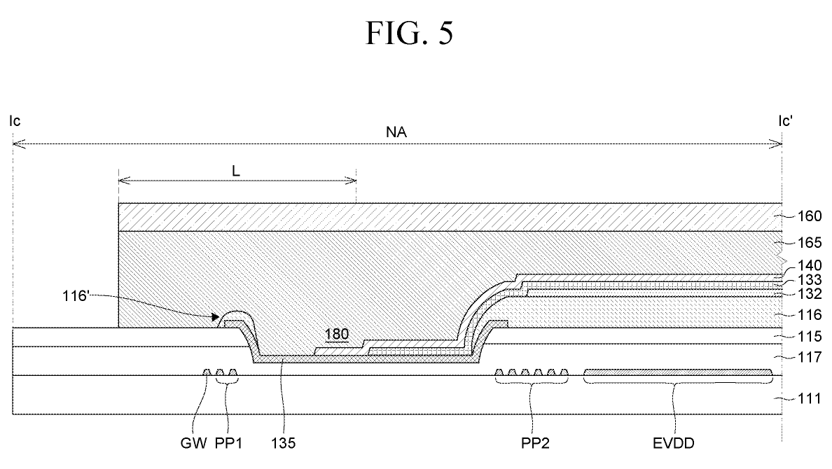

FIG. 5 is a cross-sectional view taken along line Ic-Ic' of the display device of FIG. 1.

FIG. 3 shows a part of the non-display area NA of the second side in the display device 100 of FIG. 1, and FIG. 4 shows a part of the non-display area NA of the first side in the display device 100 of FIG. 1. FIG. 5 illustrates a part of the non-display area NA of the third side of the display device 100 of FIG. 1.

For example, the first side may refer to the left side of the display device 100, the second side may refer to the upper side of the display device 100, and the third side may refer to the lower side located on the opposite side of the upper side, but is not limited thereto.

In addition, FIG. 4 schematically illustrates the GIP circuit part 108 included in the non-display area NA for the convenience of description, and in FIGS. 3 to 5, at least a part of the buffer layer 112, the gate insulating layer 113, and the interlayer insulating layer 114 are illustrated as the insulating layer 117 for the convenience of description.

Referring to FIGS. 2 to 5, in the display device 100 (see FIG. 1) of the first embodiment of the invention, the driving element 120 may be disposed on the substrate 111.

Further, the planarization layer 115 may be disposed on the driving element 120.

Further, the light emitting element 130 electrically connected to the driving element 120 may be disposed on the planarization layer 115, and the protective layer 140 may be disposed on the light emitting element 130.

The adhesive layer 165 and the encapsulation substrate 160 may be sequentially disposed on the protective layer 140. However, the display device 100 according to the first embodiment of the invention is not limited to this laminated structure.

Meanwhile, a trench 180 may be provided at an edge of the non-display area NA between the substrate 111 and the encapsulation substrate 160.

The substrate 111 may be a glass or plastic substrate. In the case of a plastic substrate, a polyimide-based or polycarbonate-based material may be used to have flexibility. In particular, polyimide is a material that can be applied to a high-temperature process and can be coated, so it is widely used as a plastic substrate.

A buffer layer 112 may be disposed on the substrate 111.

Meanwhile, although not illustrated, a light shielding layer may be disposed on the substrate 111 to block light introduced from a lower portion of the substrate 111.

A light shielding layer may be disposed on the substrate 111 at a position where the active layer 124 is to be formed. In particular, it is preferable that the size of the light shielding layer is slightly larger so as to completely cover the active layer 124.

A buffer layer 112 may be disposed on the entire surface of the substrate 111 on which the light shielding layer is formed.

The buffer layer 112 is a layer for protecting various electrodes and lines from impurities such as alkali ions discharged from the substrate 111 or the underlying layers. The buffer layer 112 may have a multilayer structure including a first buffer layer 112a and a second buffer layer 112b, but is not limited thereto. For example, the buffer layer 112 may be made of silicon oxide (SiOx), silicon nitride (SiNx), or a multi-layer thereof.

The buffer layer 112 may delay diffusion of moisture and/or oxygen permeating the substrate 111. In addition, the buffer layer 112 may include a multi-buffer and/or an active buffer. The active buffer protects the active layer 124 made of the semiconductor of the driving element 120 and may perform a function of blocking various types of defects introduced from the substrate 111. The active buffer may be formed of amorphous silicon (a-Si) or the like.

Meanwhile, in the non-display area NA, various lines and circuits for driving the light emitting element 130 of the display area AA may be disposed. For example, in the non-display area NA, link lines for transmitting signals to the plurality of sub pixels and circuits of the display area AA, driving ICs such as gate driver ICs and data driver ICs or pad parts 107 and 108 may be disposed, but are not limited thereto.

For example, the ground line GW may be disposed on the substrate 111 in the non-display area NA.

The ground line GW may be disposed at the edge of the non-display area NA excluding the upper side.

The ground line GW may be disposed adjacent to the edge of the encapsulation substrate 160.

A first anti-see-through pattern PP1 may be disposed on an inner side of the ground line GW.

The link line LW may be disposed above the substrate 111 in a part of the non-display area NA above the substrate 111. For example, the link line LW may be disposed above the substrate 111 in a part of the non-display area NA above which the open hole OH (see FIG. 1) is not disposed.

In the non-display area NA on the left and right sides, the GIP circuit part 108 may be disposed on an inner side of the trench 180.

The GIP circuit part 108 may include a control signal clock line CW, a logic unit LP, a buffer TFT unit B-TFT, and a power line GVSS, but is not limited thereto.

For example, the control signal clock line CW, the logic unit LP, the buffer TFT unit B-TFT, and the power line GVSS may be sequentially arranged from the trench 180 in a direction towards an inner portion of the display device 100. However, embodiments of the invention are not limited thereto.

In this case, the control signal clock line CW, the logic unit LP, the buffer TFT unit B-TFT, and the power line GVSS may be configured using a light shielding layer of the display area AA or a material for forming the driving element 120, but the configuration is only one example and is not limited thereto.

Further, in the non-display area NA on the third side, the second anti-see-through pattern PP2 and the second power line EVDD may be disposed on an inner side of the trench 180.

For example, the second anti-see-through pattern PP2 and the second power line EVDD may be disposed on an inner side of the trench 180 in this order, but embodiments of the invention are not limited thereto.

The second anti-see-through pattern PP2 and the second power line EVDD may be configured using a material for forming the light shielding layer or the driving element 120 of the display area AA, but embodiments of the invention are not limited thereto.

The driving element 120 may include an active layer 124, a gate insulating layer 113, a gate electrode 121, an interlayer insulating layer 114, a source electrode 122, and a drain electrode 123. Further, the driving element 120 may be electrically connected to the light emitting element 130 through the connection electrode 125 to transmit a current or a signal to the light emitting element 130. In addition to the illustrated top gate structure, the driving element 120 may be applied in various ways, such as a bottom gate structure in which the gate electrode is located below the active layer or a coplanar structure in which the gate electrode, the source electrode, and the drain electrode are disposed on the same plane.

The active layer 124 may be positioned on the buffer layer 112. The active layer 124 may be made of polysilicon (p-Si), and in this case, a predetermined area may be doped with impurities. Further, the active layer 124 may be made of amorphous silicon (a-Si) and may be made of an organic semiconductor material such as pentacene. Further, the active layer 124 may be formed of an oxide semiconductor. However, embodiments of the invention are not limited thereto

The gate insulating layer 113 may be positioned on the active layer 124. For example, the gate insulating layer 113 may be formed of an insulating inorganic material such as silicon oxide (SiOx) or silicon nitride (SiNx), or an insulating organic material.

The gate electrode 121 may be positioned on the gate insulating layer 113. For example, the gate electrode 121 may be made of various conductive materials, such as magnesium (Mg), aluminum (Al), nickel (Ni), chromium (Cr), molybdenum (Mo), tungsten (W), gold (Au), or an alloy thereof.

The interlayer insulating layer 114 may be positioned on the gate electrode 121. For example, the interlayer insulating layer 114 may be formed of an insulating material such as silicon oxide (SiOx) or silicon nitride (SiNx), or an insulating organic material.

A contact hole through which the source and drain areas are exposed may be formed by selective removal of the gate insulating layer 113 and the interlayer insulating layer 114. The source electrode 122 and the drain electrode 123 may be formed on the interlayer insulating layer 114 in a single layer or a multi-layered structure using an electrode material.

If necessary, an additional protective layer made of an inorganic insulating material may be formed to cover the source electrode 122 and the drain electrode 123.

Meanwhile, at least some of the buffer layer 112, the gate insulating layer 113, and the interlayer insulating layer 114, i.e., the insulating layer 117, may extend to the non-display area NA.

The planarization layer 115 may be disposed on the driving element 120 configured as described above.

The planarization layer 115 may have a multilayer structure including at least two layers. For example, referring to FIG. 2, the planarization layer 115 may include a first planarization layer 115a and a second planarization layer 115b, but is not limited thereto.

For example, the first planarization layer 115a is disposed to cover the driving element 120 and may be disposed to expose a part of the source electrode 122 or the drain electrode 123 of the driving element 120.

The planarization layer 115 may extend to the non-display area NA.

The planarization layer 115 may be an overcoat layer, but is not limited thereto.

A connection electrode 125 for electrically connecting the driving element 120 and the light emitting element 130 may be disposed on the first planarization layer 115a.

Further, a second planarization layer 115b may be disposed on the first planarization layer 115a and the connection electrode 125.

The second planarization layer 115b may be formed to expose a part of the connection electrode 125. Further, the drain electrode 123 of the driving element 120 and the anode 131 of the light emitting element 130 may be electrically connected by the connection electrode 125. However, embodiments of the invention are not limited thereto, and the anode may be directly electrically connected to the drain electrode without a connection electrode.

In this case, the light emitting element 130 may be configured such that the anode 131, a plurality of organic layers 132, and the cathode 133 are sequentially disposed. More particularly, the light emitting element 130 may include an anode 131 disposed on the planarization layer 115, an organic layer 132 disposed on the anode 131, and a cathode 133 disposed on the organic layer 132.

The display device 100 may be implemented in a top emission type or a bottom emission type. In the top emission method, a reflective layer made of an opaque conductive material having high reflectivity, for example, silver (Ag), aluminum (Al), gold (Au), molybdenum (Mo), tungsten (W), chromium (Cr), or an alloy thereof, may be added under the anode 131 so that light emitted from the organic layer 132 is reflected by the anode 131 and directed upward, more particularly, in the direction of the cathode 133 at the top. Conversely, in the case of the bottom emission type, the anode 131 may be made of only a transparent conductive material such as indium tin oxide (ITO), indium zinc oxide (IZO), indium gallium zinc oxide (IGZO). Hereinafter, the description will be made on the assumption that the display device 100 of the embodiments of the invention is a bottom emission type. However, embodiments of the invention are not limited thereto.

The bank 116 may be disposed on the planarization layer 115 in the remaining area except for the emission area. More particularly, the bank 116 has a bank hole exposing the anode 131 corresponding to the emission area. The bank 116 may be made of an inorganic insulating material such as silicon nitride (SiNx) or silicon oxide (SiOx), or an organic insulating material such as BCB, acrylic resin, or imide resin, without being limited thereto.

The bank 116 may extend to the non-display area NA.

The organic layer 132 may be disposed on the anode 131 exposed by the bank 116. The organic layer 132 may include an emission layer, an electron injection layer, an electron transport layer, a hole transport layer, a hole injection layer, and the like.

The organic layer 132 may extend to the non-display area NA.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), indium gallium zinc oxide (IGZO), or the like. In the case of the bottom emission type, the cathode 133 may include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 may be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

The cathode 133 may extend to the non-display area NA.

Although not illustrated, a capping layer may be disposed on the cathode 133. The capping layer may be formed of a material having a high refractive index and a high light absorption rate to reduce diffused reflection of external light.

The protective layer 140 may be disposed on the light emitting element 130 configured as described above.

The protective layer 140 may be an inorganic layer, and in this case, may be made of silicon oxide (SiOx), silicon nitride (SiNx), or a multi-layer thereof.

The protective layer 140 may extend to the non-display area NA.

The adhesive layer 165 and the encapsulation substrate 160 may be disposed on the protective layer 140.

However, embodiments of the invention are not limited thereto, and an encapsulation structure of a multilayer structure composed of a sealing member and a reinforcing substrate may be disposed on the protective layer 140.

The adhesive layer 165 may be disposed between the protective layer 140 and the encapsulation substrate 160.

For example, the adhesive layer 165 may serve to delay lateral moisture permeation.

For example, the adhesive layer 165 may further include a moisture absorbent such as a getter in addition to isobutyl rubber resin. The moisture absorbent may include calcium oxide, without being limited thereto.

The moisture absorbent may be particles having hygroscopicity and absorb moisture and oxygen from the outside to minimize the penetration of moisture and oxygen into the display area AA.

The encapsulation substrate 160 may be disposed on the adhesive layer 165.

The encapsulation substrate 160, together with the adhesive layer 165, may protect the light emitting element 130 from external moisture, oxygen, impact, and the like.

For example, the encapsulation substrate 160 may serve to prevent front moisture permeation.

For example, the encapsulation substrate 160 may be made of stainless steel (SUS) or Invar, but is not limited thereto.

In the non-display area NA, at least some layers of the insulating layer 117, more particularly, the buffer layer 112, the gate insulating layer 113, and the interlayer insulating layer 114 may extend.

Further, the planarization layer 115 may extend to the non-display area NA.

For example, the insulating layer 117 and the planarization layer 115 extending to the non-display area NA may extend to an end of the substrate 111, but are not limited thereto.

Meanwhile, in order to secure reliability such as prevention of moisture permeation in the display device 100, a minimum bezel distance is required, and the demand for slimming in the non-display area NA excluding the display area AA in which an image is displayed in accordance with the demand for slimming of the display device 100 is also increasing. However, when the cathode 133 and the organic layer 132 are deposited, a shadow area is generated due to the gap between the mask and the substrate, thereby limiting reducing of the bezel width.

Accordingly, in the first embodiment of the invention, the trench 180 from which the planarization layer 115, which is an organic layer, is removed is disposed in the shadow area in the non-display area NA.

The trench 180 is an area from which the organic layer is removed, and serves to block a path through which moisture penetrates along the organic layer to delay moisture penetration from the side surface.

In addition, the total bezel width may be reduced by converting the existing shadow area into the reliability bezel area L. The reliability bezel area L may be defined as an area from an end of the encapsulation substrate 160 to an end of the cathode 133.

The trench 180 may be formed over the non-display area NA of the left, right, and lower sides excluding the upper side in which the data pad part 107 is disposed among the four side portions of the display device 100 (see FIG. 1), but is not limited thereto. In such a case, for example, the trench 180 may be formed by removing a partial area of the insulating layer 117 and the planarization layer 115 in the non-display area NA through laser melting. Accordingly, the reliability bezel area L may be expanded, and the bezel width may be reduced by the length of the added reliability bezel area L. The trench 180 may expose at least some of the buffer layer 112, the gate insulating layer 113, and the interlayer insulating layer 114.

For example, the trench 180 may have a predetermined width to prevent deterioration in moisture permeation performance regardless of a position where the cathode 133 is formed in consideration of a process error and a margin.

Meanwhile, a first power line 135 may be disposed in the trench 180. The first power line 135 may be connected to a low potential driving voltage line to apply a voltage to the cathode 133.

For example, the first power line 135 may be disposed to cover the inside of the trench 180. More particularly, the first power line 135 may be disposed to cover the top surface and the side surface of the insulating layer 117 and the top surface and the side surface of the planarization layer 115 exposed by the trench 180.

For example, the first power line 135 may be disposed to extend along the non-display area NA located on the left, right, and lower sides of the display device 100 along the trench 180, but embodiments of the invention are not limited thereto.

For example, the bank 116 may extend to the non-display area NA to cover the inner portion of the first power line 135. Here, the inner portion of the first power line 135 may be defined as a side portion adjacent to the display area AA, which may be a side portion facing the outer portion adjacent to the non-display area NA.

The inner portion of the first power line 135 may be formed to have a predetermined taper along the inner surface of the trench 180. For example, the side surface of the trench 180 and the side portion of the first power line 135 may have a gentle taper of about 30 degrees or less. Due to this gentle taper shape, the thickness of the cathode 133 deposited thereon can be secured to about 1,000 Å or more.

The bank 116 is disposed on an inner side of the trench 180 and may be referred to as an inner bank. An outer bank 116' may be additionally disposed outside the trench 180 at a position opposite to the bank 116.

The outer bank 116' may be formed in an island shape and disposed to cover the outer portion of the first power line 135.

More particularly, the bank 116 and the outer bank 116' are separately disposed on an inner side and an outer side of the trench 180, respectively, and accordingly, a part of the top surface of the first power line 135 may be exposed without being covered by the outer bank 116'.

The outer bank 116′ may be disposed to be spaced apart from an edge of the adhesive layer 165 and the encapsulation substrate 160 by a predetermined distance.

In the first embodiment of the invention, an outer bank 116′ is formed to cover the first power line 135 and the tapered portion of the planarization layer 115, and is removed from the remaining areas. Accordingly, the water transfer velocity (WTV) may be suppressed.

In contrast, in a part of the non-display area NA above, the bank 116 may extend to the non-display area NA along the planarization layer 115, but is not limited thereto. For example, the bank 116 may extend from a part of the non-display area NA above which the open hole OH is not disposed to the non-display area NA along the planarization layer 115.

Meanwhile, in the non-display area NA, the organic layer 132 may be disposed on the bank 116.

The organic layer 132 extends to the non-display area NA, and its edge may be disposed on an inner side as compared to the edge of the bank 116, but is not limited thereto.

In the non-display area NA, the cathode 133 may be disposed on the organic layer 132.

In this case, the cathode 133 may extend into the trench 180 to cover a part of the exposed top surface of the first power line 135, but is not limited thereto.

For example, the cathode 133 may extend into the trench 180 to cover the bank 116 and the organic layer 132 on an inner side of the trench 180.

The cathode 133 may be in contact with the exposed top surface of the first power line 135, and thus may receive a low potential driving voltage from the first power line 135.

In addition, the protective layer 140 may extend into the trench 180 to cover the cathode 133, but is not limited thereto. For example, the protective layer 140 may be disposed to surround the cathode 133 except for the upper non-display area NA. On the other hand, in a part of the non-display area NA above, the protective layer 140 may cover a part of the top surface of the cathode 133. For example, the protective layer 140 may cover a part of the top surface of the cathode 133 in a part of the non-display area NA above which the open hole OH is not disposed.

For example, the protective layer 140 may be made of an inorganic insulating material.

The protective layer 140 may delay moisture permeation at the top and suppress the occurrence of defects due to dents or foreign substances.

The protective layer 140 may be made of silicon oxide (SiOx), silicon nitride (SiNx), or a multi-layered structure thereof to delay moisture permeation, but is not limited thereto.

The encapsulation substrate 160 may be disposed on the protective layer 140 with an adhesive layer 165 interposed therebetween.

Meanwhile, the display device 100 according to the first embodiment of the invention configured as described above is characterized in that the GIP circuit part 108 is disposed on an inner side of the trench 180.

The first embodiment of the invention is characterized in that the trench 180 is disposed at the edge of the non-display area NA, and the GIP circuit part 108 is disposed on an inner side of the trench 180 while being spaced apart from the trench 180 at a predetermined interval G.

In the first configuration of the embodiments of the invention, the main line (e.g., the second power line EVDD) may be rearranged into an inner side of the trench 180. The second power line EVDD may be a line for applying a high potential driving voltage to the anode 131.

In the first embodiment of the invention, the cathode 133 may extend into the trench 180 to seal the GIP circuit part 108.

Accordingly, embodiments of the invention may minimize the effect of moisture permeation, thereby improving the stability and durability of the GIP circuit part 108. Accordingly, it is possible to improve the reliability of the display device 100.

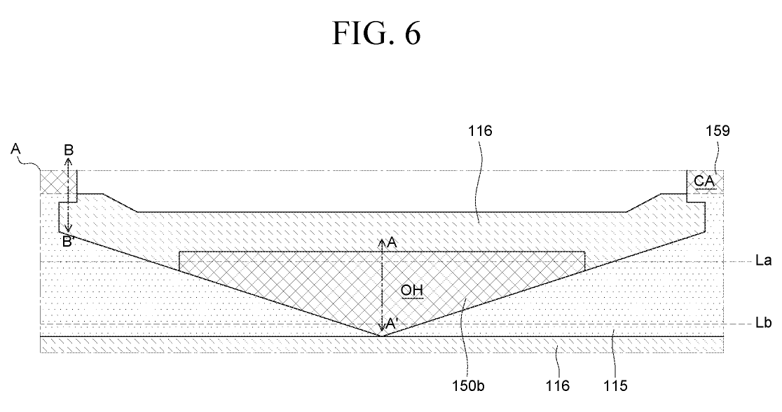

Furter in the display device 100 according to the first embodiment of the invention, an open hole OH in which the organic layers of the planarization layer 115 and the bank 116 are removed is formed in the data pad part 107 on the upper side in which the trench 180 is not disposed, such that the penetration path of oxygen and moisture in the data pad part 107 may be blocked, thereby minimizing the effect of deterioration due to moisture penetration and oxygen permeation and securing the reliability of the display device 100, which will be described in detail with reference to FIGS. 6 to 8.

FIG. 6 is an enlarged view of part A of FIG. 1.

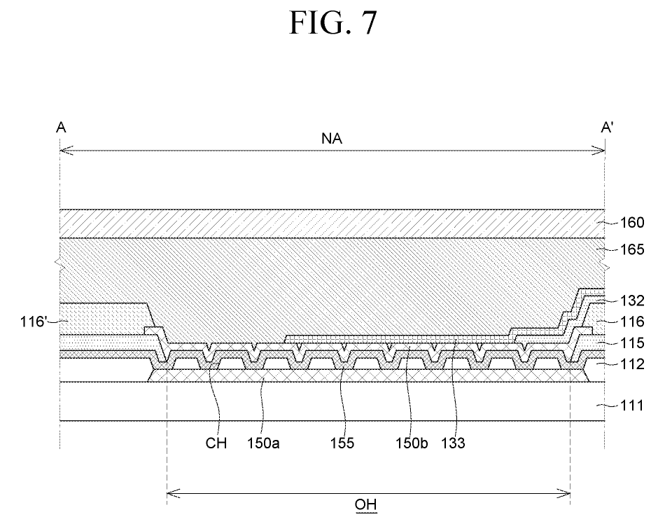

FIG. 7 is a cross-sectional view taken along line A-A' in FIG. 6.

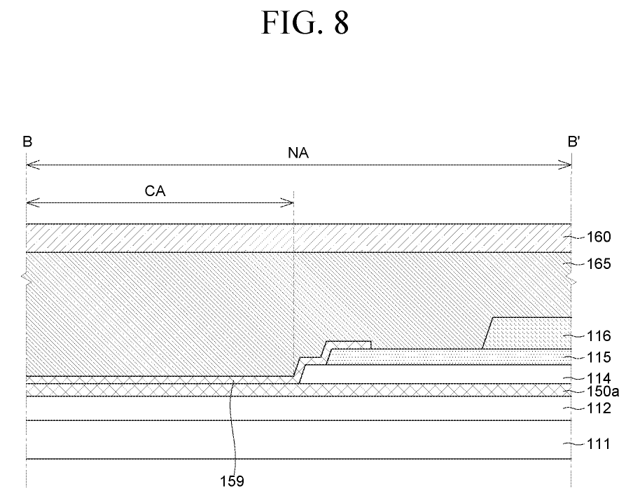

FIG. 8 is a cross-sectional view taken along line B-B' in FIG. 6.

FIGS. 6 to 8 are a plan view or a cross-sectional view illustrating a part of the non-display area NA on the second side including the open hole OH, more particularly, on the upper side. In this case, for convenience, in FIG. 6, configurations above the bank 116 are omitted.

Referring to FIGS. 6 to 8, the first line 150amay be disposed on the substrate 111 in the non-display area NA.

The first line 150a may be configured using a material for forming a light shielding layer of the display area AA, but this configuration is only an example and is not limited thereto.

The first line 150a may be electrically connected to the low potential driving voltage line 155 to lower the overall resistance. In addition, the first line 150a may transmit the low potential driving voltage supplied through the connection electrode 159 to the low potential driving voltage line 155.

The buffer layer 112 may be disposed on the first line 150a.

The buffer layer 112 may be patterned in an island shape in an area where the open hole OH is located, but is not limited thereto. A plurality of contact holes CH may be formed in the buffer layer 112 to expose a top surface of the first line 150a located therebelow.

The low potential driving voltage line 155 may be disposed on the buffer layer 112.

The low potential driving voltage line 155 may be electrically connected to the first line 150athrough the contact hole CH.

The low potential driving voltage line 155 may receive a low potential driving voltage through the first line 150a.

The low potential driving voltage line 155 may be configured using a material for forming the driving element 120 (see FIG. 2) in the display area AA (see FIG. 2), for example, a material for forming the gate electrode 121 (see FIG. 2), but the configuration is only an example and is not limited thereto.

An interlayer insulating layer 114 and a planarization layer 115 may be disposed on the low potential driving voltage line 155.

The first embodiment of the invention is characterized in that the planarization layer 115 is removed from a partial area of the data pad part 107 (see FIG. 1) to form an open hole OH.

The area in which the open hole OH is formed is an area in which the planarization layer 115 and banks 116 and 116' are not disposed, and may have a structural shape and function similar to that of the trench 180 (see FIG. 4-5). The open hole OH area is designed to secure electrical connection, and because the planarization layer 115 and the banks 116 and 116' are absent, robustness against the penetration of moisture and oxygen may be improved. Accordingly, moisture permeation and oxygen permeation-related defects may be prevented in the corresponding area.

As described above, in the first embodiment of the invention, at least one trench 180 is formed to be connected along the left, right, and lower sides to surround the display area AA, and a plurality of open holes OH are formed in the upper side to effectively reduce the bezel width and suppress the penetration of moisture and oxygen at the same time. Accordingly, it is possible to improve the overall moisture permeation prevention performance and the reliability of the display device.

For example, the open hole OH may have an inverted triangle or an inverted trapezoidal shape in which the lower side is narrowed, but is not limited to this shape.

Meanwhile, the second line 150b may be disposed in the open hole OH.

A connection electrode 159 may be disposed in the connection part CA which is supplied with a low potential driving voltage from the data pad part 107.

The second line 150b and the connection electrode 159 may be configured using a material for forming the anode 131 (see FIG. 2) of the display area AA, but such a configuration is only an example and is not limited thereto.

For example, the second line 150b may be disposed to extend on a side surface and a part of an upper portion of the planarization layer 115, including the inside of the open hole OH.

The second line 150b may be electrically connected to the low potential driving voltage line 155 and serve to lower the overall resistance. The second line 150b may transmit the low potential driving voltage supplied through the low potential driving voltage line 155 to the cathode 133.

Further, the connection electrode 159 is electrically connected to the first line 150a to transmit the low potential driving voltage supplied through the data pad part 107 to the first line 150a.

For example, the connection electrode 159 may be disposed on both upper ends of the open hole OH, but is not limited thereto.

In the non-display area NA above, the planarization layer 115 and the banks 116 and 116′ may be disposed in the remaining area excluding the open hole OH and the connection part CA.

The banks 116 and 116′ may be disposed to cover a part of the planarization layer 115 and a part of the second line 150b.

For example, the banks 116 and 116′ may be divided into a bank 116 and an outer bank 116′ by the open hole OH.

The outer bank 116' may be formed in an island shape and may be disposed to cover a part of an upper portion of the second line 150b.

In a part of the non-display area NA above, the bank 116 extends to the non-display area NA along the planarization layer 115, but in the area where the open hole OH is formed, the bank 116 is removed, so that the moisture penetration rate may be suppressed.

The organic layer 132 may be disposed on the bank 116 in the non-display area NA above the bank.

The organic layer 132 may extend into the open hole OH to cover a part of the second line 150b in the open hole OH (see the Lb line of FIG. 6), but is not limited thereto.

In the non-display area NA above, the cathode 133 may be disposed on the organic layer 132.

The cathode 133 may extend into the open hole OH to cover a part of the top surfaces of the organic layer 132 and the second line 150b in the open hole OH (see the line La of FIG. 6), without being limited thereto.

The cathode 133 may be in contact with the exposed top surface of the second line 150b and thus may receive a low potential driving voltage from the second line 150b.

The encapsulation substrate 160 may be disposed on the cathode 133 via an adhesive layer 165.

As described above, in the first embodiment of the invention, a plurality of open holes OH in which the organic layers of the planarization layer 115 and the bank 116 are removed are formed in the upper data pad part 107 in which the trench 180 is not disposed so that the penetration path of oxygen and moisture in the data pad part 107 may be blocked, thereby minimizing the effect of deterioration due to moisture permeation and oxygen permeation and securing the reliability of the display device 100.

Meanwhile, according to embodiments of the invention, a bar trench may be additionally disposed on an inner side of the trench, which will be described in detail with reference to the drawings.

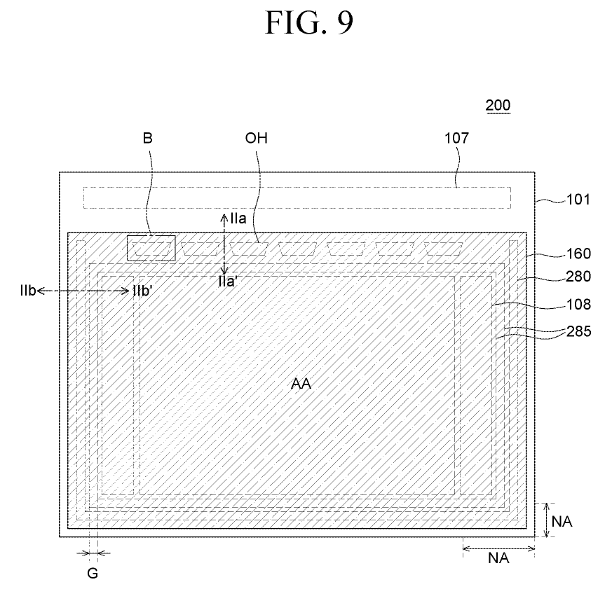

FIG. 9 is a plan view of a display device according to a second embodiment of the invention.

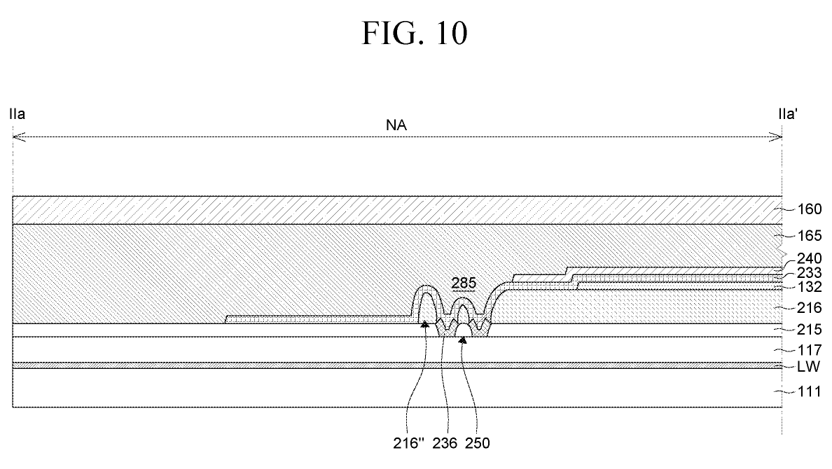

FIG. 10 is a cross-sectional view taken along line IIa-IIa' of FIG. 9.

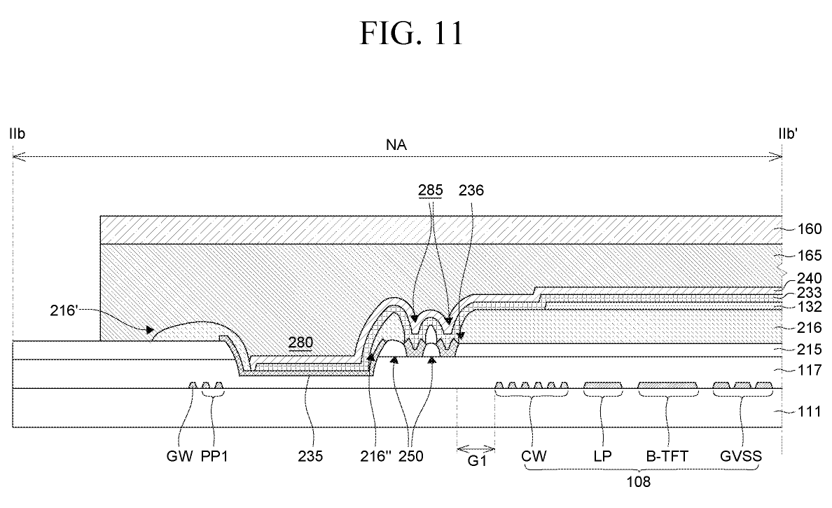

FIG. 11 is a cross-sectional view taken along line IIb-IIb' of FIG. 9.

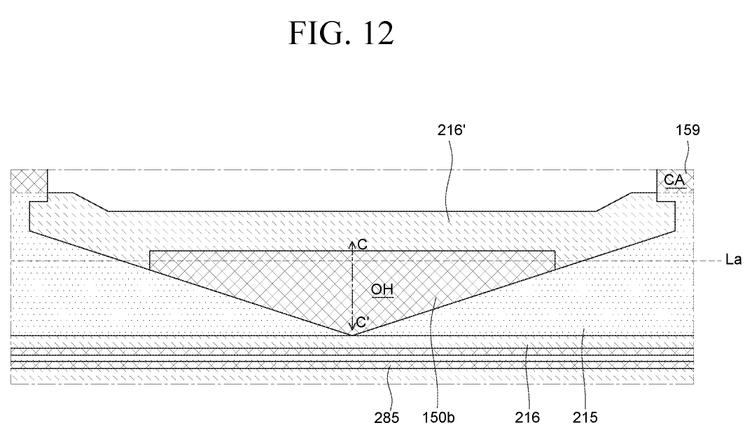

FIG. 12 is an enlarged view of part B of FIG. 9.

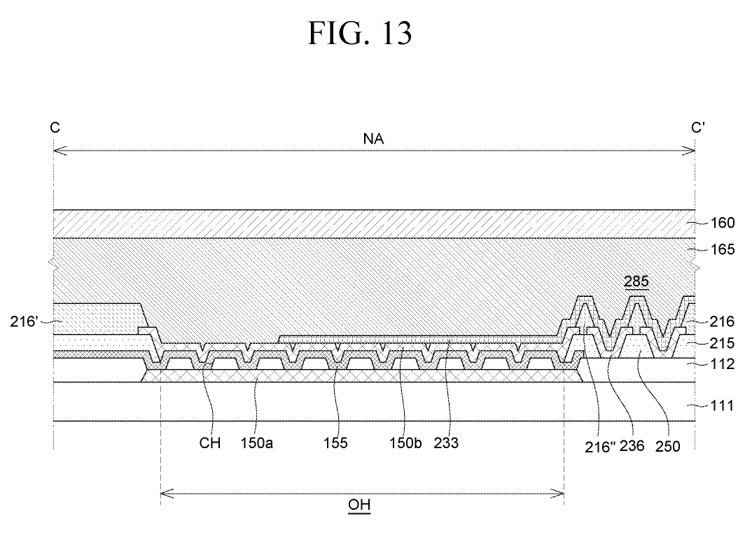

FIG. 13 is a cross-sectional view taken along line C-C' of FIG. 12.

The second embodiment of FIGS. 9 to 13 has a different trench 280 and 285 configuration than the first embodiment of FIGS. 1 to 8 described above, and the other configuration is substantially the same, so that a redundant description will be omitted. The same components will be denoted by the same reference numerals. Hereinafter, description of the same reference numerals may refer to FIGS. 1 to 8.

FIG. 10 illustrates a part of the non-display area NA of the second side of the display device 200 of FIGS. 9 and 11 illustrates a part of the non-display area NA of the first side of the display device 200 of FIG. 9.

In FIG. 11, for the convenience of description, the GIP circuit part 108 in the non-display area NA is schematically illustrated. Further, in FIGS. 10 and 11, for convenience, at least some of the buffer layer, the gate insulating layer, and the interlayer insulating layer are illustrated as the insulating layer 117.

FIGS. 12 and 13 are a plan view and a cross-sectional view illustrating a part of the non-display area NA on the second side including the open hole OH, more particularly, on the upper side. In this case, for convenience, configurations on the upper portions of the banks 216 and 216′ are omitted.

First, referring to FIGS. 9 to 11, in the display device 200 according to the second embodiment of the invention, a planarization layer 215 may be disposed on the substrate 111.

The ground line GW may be disposed on the substrate 111 in the non-display area NA excluding the upper side.

A first anti-see-through pattern PP1 may be disposed on an inner side of the ground line GW.

The link line LW may be disposed above the substrate 111 in a part of the non-display area NA on the upper side. More particularly, the link line LW may be disposed above the substrate 111 in a part of the non-display area NA above which the open hole OH (see FIG. 12) is not disposed.

In the non-display area NA on the left and right sides of the second embodiment of the invention, the GIP circuit part 108 may be disposed on an inner side of the trenches 280 and 285.

The GIP circuit part 108 may include a control signal clock line CW, a logic unit LP, a buffer TFT unit B-TFT, and a power line GVSS, but is not limited thereto.

A bank 216 may be formed on the planarization layer 215 in the remaining area except for the emission area.

The insulating layer 117, the planarization layer 215, and the bank 216 may extend to the non-display area NA.

Meanwhile, in the second embodiment of the invention, a plurality of trenches 280 and 285 are disposed in the shadow area in the non-display area NA.

The trenches 280 and 285 may include a first trench 280 and a plurality of second trenches 285.

The first trench 280 may be formed over the non-display area NA of the left, right, and lower sides excluding the upper side where the data pad part 107 is disposed, among the four side portions of the display device 200 (see FIG. 9), but is not limited thereto. In this case, for example, the first trench 280 may be formed by removing a partial area of the insulating layer 117 and the planarization layer 215 in the non-display area NA. Accordingly, for example, the first trench 280 may expose at least some of the buffer layer, the gate insulating layer, and the interlayer insulating layer.

The second trench 285 may be formed over the four side portions of the display device 200, more particularly, the non-display areas NA on the upper side, left, right, and lower sides (see FIG. 9), but is not limited thereto. In this case, for example, the second trench 285 may be formed by removing a portion of the planarization layer 215 of the non-display area NA. Further, for example, the second trench 285 may expose at least some of the buffer layer, the gate insulating layer, and the interlayer insulating layer.

A plurality of second trenches 285 may be disposed.

The first trench 280 may have a width greater than that of the second trench 285. For example, the first trench 280 may be referred to as an OC hole, and the second trench 285 may be referred to as a bar trench.

For example, a plurality of dams 250 may be disposed between the second trenches 285.

For example, the plurality of dams 250 may be disposed between the first trench 280 and the second trench 285 and between the second trench 285, but is not limited thereto.

The dam 250 may be configured as a planarization layer 215, but is not limited thereto.

The dam 250 may have a lower height than the surrounding planarization layer 215, but is not limited thereto.

Meanwhile, a first-1 power line 235 may be disposed in the first trench 280.

The first-1 power line 235 may be disposed to cover the inside of the first trench 280. More particularly, the first-1 power line 235 may be disposed to cover upper and side surfaces of the insulating layer 117 and the planarization layer 215 exposed by the first trench 280.

In this case, the first-1 power line 235 may be disposed along the first trench 280 across the non-display area NA of the left, right, and lower sides of the display device 200, but is not limited thereto.

In addition, the first-2 power line 236 may be disposed on an inner side of the second trench 285.

The first-2 power line 236 may be disposed to cover the inside of the second trench 285. That is, the first-2 power line 236 may be disposed to cover the side surface and a part of the top surface of the insulating layer 117 and the dam 250 exposed by the second trench 285.

In this case, the first-2 power line 236 may be disposed along the second trench 285 over the non-display area NA of the upper side, left, right, and lower sides of the display device 200, but is not limited thereto.

The first-1 power line 235 and the first-2 power line 236 may be electrically connected to the low-potential driving voltage line to apply a voltage to the cathode 233.

For example, an outer bank 216′ separated from the bank 216 in an island shape and an inner bank 216" may be disposed outside the GIP circuit part 108.

For example, the outer bank 216' may cover the outer portion of the first-1 power line 235 in an island shape. Further, the outer bank 216' and the inner bank 216" may be separated and disposed on both sides around the first trench 280, and a part of the top surface of the first-1 power line 235 may be exposed without being covered by the outer bank 216'.

The inner bank 216" may cover the inner portion of the first-1 power line 235 and/or the side portion of the first-2 power line 236 in an island shape. More particularly, the inner bank 216" may cover the inner portion of the first-1 power line 235 and the side portion of the first-2 power line 236, and the other inner bank 216" may cover the side portion of one first-2 power line 236 and the side portion of the other first-2 power line 236.

Meanwhile, in the non-display area NA, the organic layer 132 may be disposed on the bank 216.

The organic layer 132 extends to the non-display area NA, and its edge may be disposed on an inner side as compared to the edge of the bank 216, but is not limited thereto.

In the non-display area NA, the cathode 233 may be disposed on the organic layer 132.

In this case, the cathode 233 may extend into the first trench 280 to cover a part of the exposed top surface of the first-1 power line 235, but is not limited thereto.

For example, except for a part of the non-display area NA on the upper side, the cathode 233 may extend into the first trench 280 to cover the inner bank 216" and the first-2 power line 236. On the other hand, in a part of the non-display area NA on the upper side, the cathode 233 may extend to the non-display area NA to cover the inner bank 216" and the second trench 285. More particularly, in a part of the non-display area NA above which the open hole OH is not disposed, the cathode 233 may extend to the non-display area NA so as to cover the inner bank 216" and the second trench 285 disposed therein.

The cathode 233 may be in contact with the exposed top surface of the first-1 power line 235 to receive a low-potential drive voltage from the first-1 power line 235.

In addition, the protective layer 240 may extend into the trenches 280 and 285 to cover the cathode 233, but is not limited thereto. In this case, for example, the protective layer 240 may be disposed to surround the cathode 233 except for the non-display area NA on the upper side. On the other hand, in a part of the non-display area NA above, the protective layer 240 may cover a part of the top surface of the cathode 233 on an inner side of the second trench 285. However, the embodiments of the invention are not limited thereto, and the protective layer 240 may cover the inside of the second trench 285.

The encapsulation substrate 160 may be disposed on the protective layer 140 with an adhesive layer 165 interposed therebetween.

Meanwhile, the display device 200 according to the second embodiment of the invention configured as described above is characterized in that the GIP circuit part 108 is disposed on an inner side of the second trench 285.

The second embodiment of the invention is characterized in that the first trench 280 and the plurality of second trenches 285 are disposed at the edge of the non-display area NA, and the GIP circuit part 108 is disposed on an inner side of the second trench 285 while being spaced apart from the innermost second trench 285 at a predetermined interval G1.

As described above, in the second embodiment of the invention, a plurality of second trenches 285 are additionally disposed in the first trench 280 to further delay the moisture penetration rate to the side surface of the display device 200. Further, in the second embodiment of the invention, the GIP circuit 108 is disposed on an inner side of the second trench 285 provided further inward than the first trench 280 to more effectively suppress the penetration of moisture or oxygen.

Referring to FIGS. 12 and 13, the first line 150amay be disposed on the substrate 111 in the non-display area NA.

The buffer layer 112 may be disposed on the first line 150a.

The low potential driving voltage line 155 may be disposed on the buffer layer 112.

The low potential driving voltage line 155 may be electrically connected to the first line 150athrough the contact hole CH.

A planarization layer 215 may be disposed on the low potential driving voltage line 155.

In the second embodiment of the invention, the planarization layer 215 may be removed from a partial area of the data pad part 107 (see FIG. 9) to form an open hole OH.

The second line 150b may be disposed in the open hole OH.

Further, a connection electrode 159 may be disposed in the connection part CA.

In the second embodiment of the invention, the second trench 285 may be disposed in the shadow area in the non-display area NA on the upper side.

For example, a plurality of dams 250 may be disposed between the second trenches 285.

The first-2 power line 236 may be disposed in the second trench 285.

A planarization layer 215 and banks 216, 216', and 216" may be disposed in the remaining area of the non-display area NA on the upper side except for the open hole OH and the connection part CA.

For example, the banks 216, 216', and 216" may be separated into a bank 216 and an outer bank 216' and an inner bank 216" by an open hole OH and a second trench 285. More particularly, for example, an outer bank 216′ separated from the bank 216 in an island shape and an inner bank 216" may be disposed outside the bank 216.

In this case, the outer bank 216′ may cover the outer portion of the second line 150bin the form of an island. The outer bank 216′ and the inner bank 216" may be separated and disposed on both sides with respect to the open hole OH, and a part of the top surface of the second line 150b may be exposed without being covered by the outer bank 216′.

The inner bank 216" may cover the inner portion of the second line 150band/or the side portion of the first-2 power line 236 in the form of an island. More particularly, the inner bank 216" may cover a plurality of inner side portions, one inner bank 216" may cover the inner side portion of the second line 150b and the side portion of the first-2 power line 236, and the other inner bank 216" may cover the side portion of one first-2 power line 236 and the side portion of another first-2 power line 236.

In the non-display area NA above, the cathode 233 may be disposed on the bank 216 and the inner bank 216".

For example, the cathode 233 may extend into the open hole OH to cover a part of the top surfaces of the bank 216, the second trench 285, and the second line 150b in the open hole OH (see the La line of FIG. 12), but is not limited thereto.

The encapsulation substrate 160 may be disposed on the cathode 233 via an adhesive layer 165.

Meanwhile, the embodiments of the invention may further include an oxygen getter in the adhesive layer, which will be described in detail with reference to the drawings.

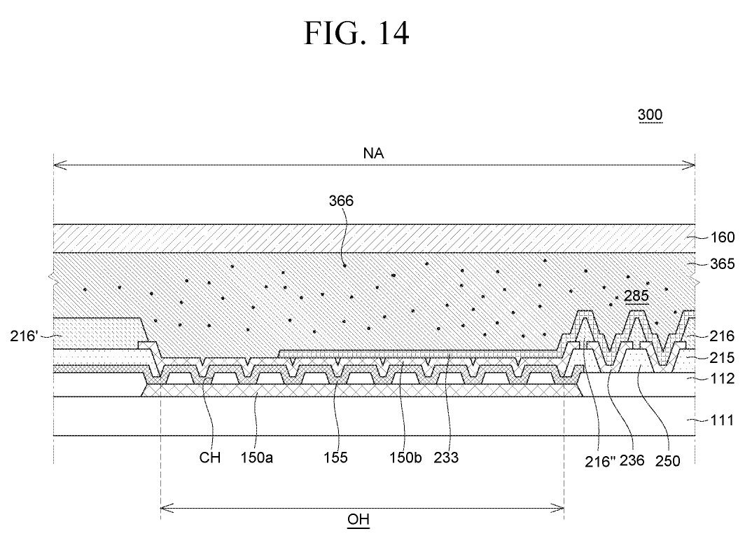

FIG. 14 is a cross-sectional view of a display device according to a third embodiment of the invention.

The third embodiment of the invention shown in FIG. 14 is substantially the same as the second embodiment of the invention shown in FIGS. 9-13 except that an adsorption particle 366 is added to the adhesive layer 365. Therefore, repeated descriptions of the identical components will be omitted. The same components will be denoted by the same reference numerals. Hereinafter, description of the same reference numerals may refer to FIGS. 1-13.

FIG. 14 is a cross-sectional view illustrating a part of an upper non-display area NA, specifically, a part of an upper non-display area NA including an open hole OH, in the display device 300 according to the third embodiment of the invention.

Referring to FIG. 14, an encapsulation substrate 160 may be disposed on the cathode 233 via an adhesive layer 365.

In this case, according to the third embodiment of the invention, the adhesive layer 365 may further include adsorption particles 366.

The adsorption particles 366 may be composed of fine particles capable of capturing (adsorbing) oxygen. Accordingly, it is possible to perform a function of blocking diffusion of oxygen by directly absorbing oxygen introduced from the outside and penetrating into the inside.

The adsorption particles 366 may include a moisture absorbent such as a getter. The moisture absorbent may include calcium oxide (CaO), without being limited thereto.

For example, the adsorption particles 366 may include a reduced metal oxide (MOn-x) such as reduced cerium oxide (CeO2-x), without being limited thereto.

For example, cerium oxide (CeO2-x) has a blue black color, but when oxygen is adsorbed, the color may change to light gray.

In this way, when the metal oxide (MOn-x) is reduced to make a hole (vacancy) of the oxygen defect, it is possible to absorb oxygen by reacting with oxygen of the outside air.

Meanwhile, the cathode according to embodiments of the invention may be disposed to completely cover the inside of the open hole, and this will be described in detail with reference to the drawings.

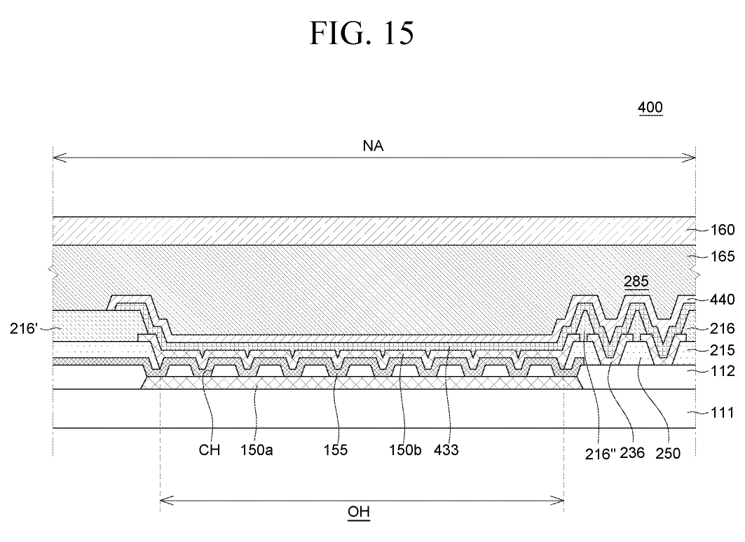

FIG. 15 is a cross-sectional view of a display device according to a fourth embodiment of the invention.

A fourth embodiment of FIG. 15 is substantially the same as the second embodiment of FIGS. 9 to 13 described above except for configurations of a cathode 433 and a protective layer 440, and accordingly, their common features are not described. Hereinafter, description of the same reference numerals may refer to FIG. 1 through FIG. 14.

FIG. 15 is a cross-sectional view illustrating a part of the non-display area NA on the upper side including the open hole OH.

Referring to FIG. 15, in the display device 400 according to the fourth embodiment of the invention, an open hole OH may be formed in a partial edge of the non-display area NA between the substrate 111 and the encapsulation substrate 160.

More particularly, the open hole OH in which the organic layer of the planarization layer 215 and the bank 216 is removed may be formed at the edge of the non-display area NA on the upper side.

The second line 150b may be disposed in the open hole OH.

In addition, a second trench 285 may be formed on an inner side of the open hole OH.

For example, a plurality of dams 250 may be disposed between the second trenches 285.

The first-2 power line 236 may be disposed in the second trench 285.

In the non-display area NA above, the planarization layer 215 and the banks 216, 216', and 216" may be disposed in the remaining area excluding the open hole OH and the connection part CA (see FIGS. 6, 12).

In the non-display area NA above, the cathode 433 may be disposed on the bank 216 and the bank 216 on an inner side.

The cathode 433 according to the fourth embodiment of the invention may extend to the non-display area NA so as to cover the entire open hole OH. More particularly, for example, the cathode 433 may extend to the non-display area NA so as to cover the top surface of the exposed second line 150b including the inner bank 216" and the second trench 285 and a part of the side surface of the outer bank 216′.

In addition, the protective layer 440 may extend to the non-display area NA to cover the cathode 433, but is not limited thereto. Further, for example, the protective layer 440 may extend to the non-display area NA to surround the cathode 433.

According to embodiments of the invention, by forming a trench in the shadow area generated by the use of the deposition mask, it is possible to effectively reduce the bezel width and suppress the penetration of moisture and oxygen, thereby improving the moisture permeation prevention performance and reliability.

According to embodiments of the invention, by forming an open hole in which the organic layers of the planarization layer and the bank are removed in the data pad part, the penetration path of oxygen and moisture in the data pad part can be blocked, thereby minimizing the effect of deterioration due to moisture permeation and oxygen permeation and securing the long-term reliability of the display device.

According to embodiments of the invention, by adding a bar-shaped trench structure, it is possible to effectively block the penetration of oxygen and moisture from the external environment, thereby preventing the degradation of the organic light emitting element.

According to embodiments of the invention, a trench and a bar-shaped trench structure may be formed in an existing manufacturing process without adding a separate process, thereby securing manufacturing efficiency and improving design flexibility.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate including a display area and a non-display area;
an insulating layer and a planarization layer disposed above the substrate and extending from the display area to the non-display area;
at least one trench disposed in the non-display area and configured by removing at least one of the insulating layer and the planarization layer;
a bank disposed on the planarization layer and extending to the non-display area;
an organic layer disposed on the bank;
a cathode disposed on the organic layer and extending to the trench;
a gate pad part disposed on a first side of the non-display area;
a data pad part disposed on a second side of the non-display area; and
a plurality of open holes configured by removing the planarization layer on the data pad part.

2. The display device according to claim 1, wherein the trench is disposed to surround the display area excluding the second side.

3. The display device according to claim 1, further comprising a gate-in-panel (GIP) circuit part disposed in the gate pad part,
wherein the GIP circuit part is disposed on an inner side of the trench.

4. The display device according to claim 2, further comprising a first power line disposed in the trench and covering an inside of the trench.

5. The display device according to claim 4, wherein the cathode extends into the trench to cover a part of a top surface of the first power line, and
wherein the cathode is in contact with the top surface of the first power line.

6. The display device according to claim 1, further comprising a protective layer disposed above the cathode,
wherein in the non-display area of the second side, the protective layer covers a part of a top surface of the cathode, and
wherein in the non-display area other than the second side, the protective layer is disposed to surround the cathode.

7. The display device according to claim 1, wherein the trench includes:
a first trench disposed over the non-display area excluding the second side; and
a second trench positioned on an inner side of the first trench and disposed over the non-display area on four sides.

8. The display device according to claim 7, wherein the first trench is configured by removing a partial area of the insulating layer and the planarization layer in the non-display area, and
wherein the second trench is configured by removing a partial area of the planarization layer in the non-display area.

9. The display device according to claim 7, wherein a plurality of second trenches are disposed, and
wherein a plurality of dams configured as the planarization layer are disposed between the plurality of second trenches.

10. The display device according to claim 7, further comprising:
a first-1 power line disposed in the first trench to cover an inside of the first trench; and
a first-2 power line disposed in the second trench to cover an inside of the second trench.

11. The display device according to claim 1, further comprising:
a first line disposed over the substrate of the data pad part; and
a buffer layer disposed over the first line and patterned into an island shape in an area where the open hole is located.

12. The display device according to claim 11, wherein a plurality of contact holes are formed in the buffer layer to expose a top surface of the first line.

13. The display device according to claim 12, further comprising a low potential driving voltage line disposed on the buffer layer,
wherein the low potential driving voltage line is electrically connected to the first line through the contact hole.

14. The display device according to claim 1, wherein, in a plan view, the open hole has an inverted triangle or an inverted trapezoidal shape that narrows in a downward direction.

15. The display device according to claim 1, further comprising:
a second line disposed inside the open hole; and
a connection electrode disposed in a connection portion at both upper ends of the open hole in a plan view,
wherein, in a non-display area on the second side, the planarization layer and the bank are disposed in a remaining area excluding the open hole and the connection portion.

16. The display device according to claim 15, wherein the organic layer extends into the open hole to cover a part of the second line in the open hole,
wherein the cathode extends into the open hole to cover the organic layer in the open hole and a part of a top surface of the second line, and
wherein the cathode is in contact with the top surface of the second line.

17. The display device according to claim 1, wherein an encapsulation substrate is disposed over the cathode above with an adhesive layer interposed therebetween, and
wherein the adhesive layer further includes adsorbent particles.

18. The display device according to claim 17, wherein the adsorbent particles include a reduced metal oxide (MOn-x).

19. The display device according to claim 1, further comprising a protective layer disposed on the cathode,
wherein the cathode extends to the non-display area to cover the entire open hole, and
wherein the protective layer extends to the non-display area to surround the cathode.

20. A display device, comprising:
a substrate including a display area and a non-display area having four sides disposed to enclose the display area;
a first trench disposed over three sides excluding one side of the non-display area and configured by removing a portion of an insulating layer and a planarization layer;
a second trench disposed over the non-display area on the four sides and on an inner side of the first trench, and configured by removing the planarization layer; and
a plurality of open holes formed on one side of the non-display area and outside the second trench and configured by removing the planarization layer.
